(19) United States
(12) Patent Application Publication
(10) Pub. No.: US 2008/0121513 A1
(43) Pub. Date: May 29, 2008

(54) PROCESSING CONDITION OBTAINING METHOD AND THIN-FILM FORMING METHOD

(75) Inventors: Takumi UESUGI, Tokyo (JP); Tetsuro SASAKI, Tokyo (JP); Satoshi MIURA, Tokyo (JP)

Correspondence Address: GREENBLUM & BERNSTEIN, P.L.C., 1950 ROLAND CLARKE PLACE, RESTON, VA, 20191, US

(73) Assignee: TDK CORPORATION, Tokyo (JP)

(21) Appl. No.: 11/680,780

(22) Filed: Mar. 1, 2007

Related U.S. Application Data
(60) Provisional application No. 60/867,143, filed on Nov. 24, 2006.

(51) Int. Cl. C23C 14/34; C23C 14/52

(52) U.S. Cl. 204/192.1; 427/445

(57) ABSTRACT

A processing condition obtaining method obtains a processing condition that makes it possible to form an extremely thin film of a desired thickness. This processing condition obtaining method obtains the processing condition, which shows the relationship between the processing time of a thin-film forming process and the thickness of a thin film formed by such process, by measuring the thickness Ta of a thin film formed by carrying out the thin-film forming process Na times (where Na is a natural number of two or greater) with the processing time set at L seconds (where L is a real number), measuring the thickness Tb of a film formed by carrying out the thin-film forming process Nb times (where Nb is a natural number of two or greater) with the processing time set at M seconds (where M is a real number that differs to L), and obtaining the processing condition with the thickness of a thin film formed by the thin-film forming process with the processing time set at L seconds as Ta/Na and the thickness of a thin film formed by the thin-film forming process with the processing time set at M seconds as Tb/Nb.

### CROSS-REFERENCE TO RELATED APPLICATIONS

This application claims the benefit of U.S. Provisional Application No. 60/867,143, filed Nov. 24, 2006.

### BACKGROUND OF THE INVENTION

1. Field of the Invention

The present invention relates to a processing condition obtaining method that obtains a processing condition showing a relationship between processing time (i.e., the length of the processing period) and the thickness of a thin film formed using a variety of methods such as vacuum deposition, wet plating, sputtering, and ion plating, and also to a thin-film forming method that forms a thin film in a processing time set based on the obtained processing condition.

2. Description of the Related Art

The miniaturization of electronic appliances has made it essential to form thin films during the manufacturing of electronic components, information media, and the like. For example, Japanese Laid-Open Patent Publication No. 2001-226772 discloses a thin-film forming method that forms a conductive thin film on the surface of a piezoelectric substrate during the manufacturing of an acoustic surface wave device. In this thin-film forming method, a piezoelectric substrate whose surface has been washed is set inside a sputtering device and a thin-film forming process that forms a thin film by sputtering is carried out for a predetermined time to form a conductive thin film with the desired thickness on the surface of the piezoelectric substrate.

As shown by the solid line L11 in FIG. 10, a phenomenon occurs in a sputtering device for forming this type of thin film whereby the thin-film formation rate (i.e., the amount of thin film formed per unit processing time) falls just after the start and just before the end of the thin-film forming process. This phenomenon is caused, for example, by the amount of sputter that is scattered from the target and adheres to the coated object falling in accordance with the extent to which the shutter of a shutter mechanism is only partially open during the opening and closing of the shutter. More specifically, during a period from the start t0 of the thin-film forming process (i.e., when the shutter opening operation starts) to the time t1 where the shutter becomes completely open and during a period from the time t2 where the shutter closing operation starts to the time t3 where the shutter becomes completely closed (i.e., when the thin-film forming process ends), the formation rate of the thin film falls compared to the period from the time t1 to the time t2 where the shutter is completely open.

In this way, with a thin-film forming method where a period with a reduced thin-film formation rate (hereinafter referred to as a “different formation rate period”) is present from the start until the end of the process (i.e., a thin-film forming method with a fluctuating formation rate) and where the different formation rate period has a fixed length regardless of the total processing time, when the processing time is changed to form a thin film with a desired thickness, the proportion of the different formation rate period to the total processing time will change. This means that for a thin-film forming method that uses the sputtering device described above, if, when attempting to form a thin film with a thickness z4 that is half of a thickness z3, the thin-film forming process is carried out for a processing time (i.e., the period from the time t0 to t4) that is half the processing time (i.e., the period from the time t0 to t3) required to form a thin film with the thickness z3, as shown by the dotted line L12 in FIG. 10, a problem occurs in that the thickness z4a of the formed thin film will be thinner than the desired thickness z4.

On the other hand, to solve the problem described above due to the change in the proportion of the different formation rate period to the total processing time, the patent publication mentioned above discloses a method that uses the procedure described below to obtain a processing condition for the relationship between the processing time of a thin-film forming process and the thickness of the thin film formed by the thin-film forming process. First, a plurality of piezoelectric substrates are prepared and a thin-film forming process that forms a conductive thin film is successively carried out for the respective piezoelectric substrates with different processing times. By doing so, conductive thin films with different thicknesses are formed on the respective piezoelectric substrates in accordance with the processing times. Next, the electrical resistance (the sheet resistance) of the conductive thin film is measured for the respective piezoelectric substrates as one example of a parameter that changes in accordance with the processing time of the thin-film forming process. After this, based on the measurement results (i.e., the electrical resistance) and the processing times required to form the conductive thin films, it is possible to find a relational expression (i.e., a processing condition) showing the relationship between the processing time and the electrical resistance of the conductive thin film. Here, the electrical resistance of the conductive thin film falls in proportion to the thickness of the thin film. Accordingly, by obtaining the electrical resistance of a conductive thin film with the desired thickness in advance, it is possible to calculate the processing time that can form a conductive thin film with that resistance based on the relational expression described above.

Also, as another method of solving the problem described above due to the change in the proportion of the different formation rate period to the total processing time, the patent publication mentioned above discloses a method that instead of measuring the electrical resistance of the conductive thin film in the processing condition obtaining method described above, measures the thickness of the thin film (another example of a parameter that changes in accordance with the processing time of the thin-film forming process) and obtains a relational expression showing the relationship between the processing time and the thickness of the formed thin film (hereinafter referred to as a “relational expression relating to thickness”). More specifically, first a first thin film is formed by carrying out the thin-film forming process for a processing time from time t0 to time t91 as shown by the dotted line L13 of FIG. 11, and a second thin film is also formed by carrying out the thin-film forming process for a processing time from time t0 to time t92 (i.e., a different processing time to the period from time t0 to t91) as shown by the dot-dash line L14 in FIG. 11. Next, the thicknesses z91 and z92 of the respective thin films are measured and a relational expression relating to thickness (the direct function shown by the solid line L15 in FIG. 11: a “processing condition”) is obtained based on the measured thicknesses z91 and z92 and the processing times required to form both thin films. By doing so, it becomes possible to form a conductive thin film with the processing time required to form a thin film of the desired thickness set based on the obtained relational expression.

However, by investigating the thin-film forming method described above, the present inventors found the following problem. With the conventional thin-film forming method, a relational expression (i.e., processing condition) relating to thickness is obtained before the thin-film forming process and the processing time required to form a thin film with the desired thickness is calculated based on the obtained relational expression. When doing so, with the conventional thin-film forming method, to solve the problem caused by changes in the proportion of the different formation rate period to the total processing time, as described earlier the relational expression is obtained as a processing condition by carrying out the thin-film forming process for at least two different processing times and measuring the thicknesses of the respective thin films.

At present, to miniaturize electronic components further and to further increase the density of information media, it is necessary to form thin films with even smaller thicknesses. However, it is difficult to correctly measure both the thickness and values such as the resistance described above for extremely thin films. Accordingly, as shown in FIG. 11, even if it is possible to correctly measure the thickness z92 of the second thin film formed by carrying out the thin-film forming process for a processing time from time t0 to time t92, for example, there will still be the risk of a measurement error occurring for the thickness z91 of the first thin film formed by carrying out the thin-film forming process for a processing time from time t0 to time t91, which can result in the thickness being erroneously measured as a thickness z91a. Here, although the direct function shown by the solid line L15 in FIG. 11 should actually be obtained, based on the thickness z91a for which the measurement error has occurred, the thickness z92 that has been correctly measured, and the processing times required to form both thin films, the relational expression relating to thickness is obtained as the direct function shown by the dashed line L16 in FIG. 11.

It should be clear that if the time required to form a thin film of the desired thickness is calculated based on a direct function (i.e., processing condition) obtained using a thickness for which a measurement error has occurred, the thickness of the formed thin film will differ to the desired thickness. More specifically, as shown in FIG. 12, when a thin film with a thickness z81 is to be formed, for example, and the thin-film forming process is carried out with the processing time set at time t0 to time t81 based on the obtained relational expression, the thin-film forming process will be executed as shown by the dot-dot-dash line L17 in FIG. 12 and a thin film will be formed with a thickness of z81a that is thicker than the desired thickness z81. In this way, with a method that obtains a processing condition (i.e., a relational expression) based on the thicknesses of thin films formed by carrying out the thin-film forming process with at least two different processing times, even if an extremely slight measurement error occurs for the thickness, a processing condition that differs to the actual processing condition (i.e., relational expression) will be obtained.

On the other hand, to avoid the situation where a measurement error occurs when measuring thickness during the obtaining of a relational expression (processing condition) relating to thickness, it would be conceivably possible to obtain the relational expression by forming a thin film that is sufficiently thicker than the thin film that is actually to be formed (i.e., by forming a thin film that is thick enough to be measured correctly). However, when such method is used, even if an extremely small measurement error occurs during the measurement of thickness, the error between the processing time calculated based on the obtained relational expression (i.e., the direct function shown by the dashed line L16 in FIGS. 11 and 12) and the processing time calculated based on the correct relational expression (i.e., the direct function shown by the solid line L15 in FIGS. 11 and 12) will increase as the thickness of the thin film to be formed decreases. In this way, due to the difficulty in correctly measuring the thickness of an extremely thin film, it is difficult to obtain a correct processing condition (i.e., relational expression) for extremely thin films. This results in the problem of it being difficult to form an extremely thin film with the desired thickness using the conventional thin-film forming method.

### SUMMARY OF THE INVENTION

The present invention was conceived in view of the problem described above and it is a principal object of the present invention to provide a processing condition obtaining method and a thin-film forming method that obtain a processing condition that enables an extremely thin film to be formed with a desired thickness.

To achieve the stated object, a processing condition obtaining method according to the present invention obtains a processing condition showing the relationship between a processing time of a thin-film forming process and the thickness of a thin film formed by the thin-film forming process, the method including: measuring the thickness Ta of a thin film formed by carrying out the thin-film forming process with the processing time set at L seconds (where L is a real number) Na times (where Na is a natural number of two or greater); measuring the thickness Tb of a thin film formed by carrying out the thin-film forming process with the processing time set at M seconds (where M is a real number that differs to L) Nb times (where Nb is a natural number of two or greater); and obtaining the processing condition with the thickness of the thin film formed by the thin-film forming process with the processing time set at L seconds (that is, the thickness of a thin film after L seconds have elapsed from the start of the thin-film forming process) as Ta/Na and with the thickness of the thin film formed by the thin-film forming process with the processing time set at M seconds (that is, the thickness of a thin film after M seconds have elapsed from the start of the thin-film forming process) as Tb/Nb.

According to this first processing condition obtaining method, it is possible to obtain the processing condition based on measured values (thicknesses) of relatively thick films that have been formed by carrying out a thin-film forming process multiple times. Accordingly, it is possible to sufficiently raise the measurement precision compared to a processing condition obtained based on measured values (i.e., thicknesses) of very thin films whose thicknesses are difficult to measure correctly. Also, even if a measurement error occurs for a measured value of the thickness when the processing condition is obtained, since the processing condition is obtained based on a value where the measurement error is reduced to the reciprocal of the number of processes (1/Na times, 1/Nb times), it is possible to sufficiently increase the precision. As a result, it is possible to form even an extremely thin film with the desired thickness.

Another processing condition obtaining method according to the present invention obtains a processing condition showing the relationship between a processing time of a thin-film forming process and the thickness of a thin film formed by the thin-film forming process, the method including: measuring the thickness Ta of a thin film formed by carrying out the thin-film forming process with the processing time set at L seconds (where L is a real number) Na times (where Na is a natural number of two or greater); measuring the thickness Tb of a thin film formed by carrying out the thin-film forming process with the processing time set at M seconds (where M is a real number that differs to L) Nb times (where Nb is a natural number of two or greater); and finding a processing time of X seconds required to form a thin film of a predetermined thickness Tx with the thickness of the thin film formed by the thin-film forming process with the processing time set at L seconds (that is, the thickness of a thin film after L seconds have elapsed from the start of the thin-film forming process) as Ta/Na and the thickness of the thin film formed by the thin-film forming process with the processing time set at M seconds (that is, the thickness of a thin film after M seconds have elapsed from the start of the thin-film forming process) as Tb/Nb, before measuring the thickness Tc of a thin film formed by carrying out the thin-film forming process with the processing time set at K seconds (where K is a real number) Nc times (where Nc is a natural number of two or greater) and obtaining the processing condition with the thickness of the thin film formed by the thin-film forming process with the processing time set at K seconds (that is, the thickness of a thin film after K seconds have elapsed from the start of the thin-film forming process) as Tc/Nc and with the thickness of the thin film formed by the thin-film forming process with the processing time set at X seconds (that is, the thickness of a thin film after X seconds have elapsed from the start of the thin-film forming process) as Tx.

With this second processing condition obtaining method, it is possible to obtain the processing condition based on measured values (thicknesses) of relatively thick films that have been formed by carrying out a thin-film forming process multiple times. Accordingly, it is possible to sufficiently raise the measurement precision compared to a processing condition obtained based on measured values (i.e., thicknesses) of very thin films whose thicknesses are difficult to measure correctly. Also, even if a measurement error occurs for a measured value of the thickness when the processing condition is obtained, since the processing condition is obtained based on a value where the measurement error is reduced to the reciprocal of the number of processes (1/Na times, 1/Nb times, 1/Nc times), it is possible to sufficiently increase the precision. As a result, it is possible to form even an extremely thin film with the desired thickness. In addition, by finding the processing time of X seconds required to form a thin film of a predetermined thickness Tx in advance, when subsequently obtaining the processing condition, by merely measuring the thickness Tc of a thin film formed by carrying out the thin-film forming process with a processing time set at K seconds Nc times, it is possible to obtain the processing condition with the thickness of a thin film formed by carrying out the thin-film forming process with the processing time set at K seconds as Tc/Nc and the thickness of a thin film formed by the thin-film forming process with the processing time set at X seconds as Tx. Accordingly, compared to a processing condition obtaining method that measures the thickness Ta of a thin film formed by carrying out the thin-film forming process with the processing time set at L seconds Na times and measures the thickness Tb of a thin film formed by carrying out the thin-film forming process with the processing time set at M seconds Nb times every time the processing condition is obtained, when obtaining the processing condition for the second and subsequent times, it is sufficient to form one thin film by carrying out the thin-film forming process with the processing time set at K seconds Nc times, and therefore the processing condition can be obtained in a short time.

Note that the expression “processing condition” for the two processing condition obtaining methods according to the present invention includes “various kinds of information showing the relationship between the processing time of a thin-film forming process and the thickness of a thin film formed by such thin-film forming process”, and more specifically includes information such as “a relational expression showing the relationship between processing time and thickness” and “relationship information (information such as a list of processing times for different thicknesses) in which various processing times and various thicknesses are individually associated”. Here, two thin films are formed with different processing times of “L seconds” and “M seconds” according to the processing condition obtaining methods of the present invention to solve the problem described earlier due to changes in the proportion of the different formation rate period to the total processing time. Also, the L-second thin-film forming process is carried out “Na times” and the M-second thin-film forming process is carried out “Nb times” according to the processing condition obtaining methods of the present invention to form a thin film with a thickness Ta and a thin film with a thickness Tb that are thick enough to be measured correctly. This makes it possible to sufficiently reduce measurement errors. In the same way, the K-second thin-film forming process is carried out “Nc times” to form a thin film with a thickness Tc that is thick enough to be measured correctly, which makes it possible to sufficiently reduce measurement errors.

Also, with the first processing condition obtaining method according to the present invention, it is possible to form the thin films by carrying out the Na thin-film forming processes whose processing times are set at L seconds and the Nb thin-film forming processes whose processing times are set at M seconds with Na and Nb set at an equal number. According to this processing condition obtaining method, unlike a method that obtains the processing condition based on the thickness Ta of a thin film formed by carrying out the L-second thin-film forming process three times (an example where “Na=3”) and on the thickness Tb of a thin film formed by carrying out the M-second thin-film forming process three hundred times (an example where “Nb=300”) for example, or in other words, unlike a method where Na and Nb differ, it is possible to avoid a situation where one of the thin films is formed excessively thinly or where one film is formed excessively thickly and to produce both thin films with thicknesses that can be measured with the same measurement environment (i.e., the same measurement apparatus). Accordingly, it is possible to avoid a situation where measurement errors occur due to differences in the measurement environment and therefore it is possible to obtain the processing condition with sufficiently high precision.

Also, with the second processing condition obtaining method according to the present invention, it is possible to form the thin films by carrying out the Na thin-film forming processes whose processing times are set at L seconds, the Nb thin-film forming processes whose processing times are set at M seconds, and the Nc thin-film forming processes whose processing times are set at K seconds with Na, Nb, and Nc set at an equal number. According to this processing condition obtaining method, unlike a method that obtains the processing condition based on the thickness Ta of a thin film formed by carrying out the L-second thin-film forming process three times (an example where “Na=3”) and on the thickness Tb of a thin film formed by carrying out the M-second thin-film forming process three hundred times (an example where “Nb=300”) for example, or in other words, unlike a method where Na and Nb differ, it is possible to avoid a situation where one of the thin films is formed excessively thinly or where one film is formed excessively thickly and to produce both thin films with thicknesses that can be measured with the same measurement environment (i.e., the same measurement apparatus). Accordingly, it is possible to avoid a situation where measurement errors occur due to differences in the measurement environment and therefore it is possible to obtain a calculation result (for example, a direct function) with sufficiently high precision. Also, compared to the case where Nc differs to Na and Nb, it is possible to avoid a situation where one of the thin films is formed excessively thinly or where one of the other films is formed excessively thickly and to produce the respective thin films with thicknesses that can be measured with the same measurement environment (i.e., the same measurement apparatus). Accordingly, it is possible to avoid a situation where measurement errors occur due to differences in the measurement environment and therefore it is possible to obtain the processing condition with sufficiently high precision.

Also, with the first processing condition obtaining method according to the present invention, when the processing condition that relates to formation of a thin film is obtained with sputtering as the thin-film forming process, the respective lengths of L seconds and M seconds for the present invention may both be set longer than the total of the time required by the shutter mechanism of a sputtering device to open and the time required to close. According to this processing condition obtaining method, it is possible to avoid a situation where thin-film forming processes are carried out a plurality of times for an extremely short time where the closing operation of the shutter starts before the shutter becomes completely open, and therefore it is possible to obtain the processing condition with high precision that is in line with an actual thin-film forming process.

Also, with the second processing condition obtaining method according to the present invention, when the processing condition that relates to formation of a thin film is obtained with sputtering as the thin-film forming process, the respective lengths of L seconds, M seconds, and K seconds for the present invention may each be set longer than the total of the time required by the shutter mechanism of a sputtering device to open and the time required to close. According to this processing condition obtaining method, it is possible to avoid a situation where thin-film forming processes are carried out a plurality of times for an extremely short time where the closing operation of the shutter starts before the shutter becomes completely open, and therefore it is possible to obtain the processing condition with high precision that is in line with an actual thin-film forming process.

Also, a thin-film forming method according to the present invention forms a thin film with the processing time set based on the processing condition obtained by either of the processing condition obtaining methods described above. According to this thin-film forming method, it is possible to set the processing time based on a processing condition that has sufficiently high precision and as a result, it is possible to form even an extremely thin film with the desired thickness.

### BRIEF DESCRIPTION OF THE DRAWINGS

These and other objects and features of the present invention will be explained in more detail below with reference to the attached drawings, wherein:

FIG. 1 is a block diagram showing the construction of a sputtering device;

FIG. 2 is a diagram useful in explaining the relationship between the time elapsed from the start of processing (i.e., the processing time) and the thickness of a formed thin film when obtaining a processing condition using the processing condition obtaining method according to the present invention;

FIG. 3 is another diagram useful in explaining the relationship between the time elapsed from the start of processing (i.e., the processing time) and the thickness of a formed thin film when obtaining a processing condition using the processing condition obtaining method according to the present invention;

FIG. 4 is a diagram useful in explaining the relationship between the time elapsed from the start of processing (i.e., the processing time) and the thickness of a formed thin film when forming a thin film of the desired thickness using a processing condition obtained using the processing condition obtaining method according to the present invention;

FIG. 5 is a diagram useful in explaining the thickness of the thin film when the processing time has been set after obtaining the processing condition using a conventional processing condition obtaining method;

FIG. 6 is a diagram useful in explaining the thickness of the thin film when the processing time has been set after obtaining the processing condition using a processing condition obtaining method according to the present invention;

FIG. 7 is a diagram useful in explaining the relationship between the time elapsed from the start of processing (i.e., the processing time) and the thickness of a formed thin film when obtaining a processing condition according to another embodiment of a processing condition obtaining method according to the present invention;

FIG. 8 is another diagram useful in explaining the relationship between the time elapsed from the start of processing (i.e., the processing time) and the thickness of a formed thin film when obtaining a processing condition according to another embodiment of a processing condition obtaining method according to the present invention;

FIG. 9 is a diagram useful in explaining the relationship between the time elapsed from the start of processing (i.e., the processing time) and the thickness of a formed thin film when forming a thin film of the desired thickness using a processing condition obtained using the other embodiment of a processing condition obtaining method according to the present invention;

FIG. 10 is a diagram useful in explaining the relationship between the time elapsed from the start of processing (i.e., the processing time) and the thickness of a formed thin film when forming a thin film by sputtering;

FIG. 11 is a diagram useful in explaining the relationship between the time elapsed from the start of processing (i.e., the processing time) and the thickness of a formed thin film when the processing condition is obtained using a conventional processing condition obtaining method; and

FIG. 12 is a diagram useful in explaining the relationship between the time elapsed from the start of processing (i.e., the processing time) and the thickness of a formed thin film when forming a thin film of the desired thickness using a processing condition obtained using a conventional processing condition obtaining method.

### DESCRIPTION OF THE PREFERRED EMBODIMENTS

Preferred embodiments of a processing condition obtaining method and a thin-film forming method according to the present invention will now be described with reference to the attached drawings.

First, the construction of a sputtering device 1 that forms a thin film by sputtering (one example of a “thin-film forming process” for the present invention) will be described with reference to the drawings.

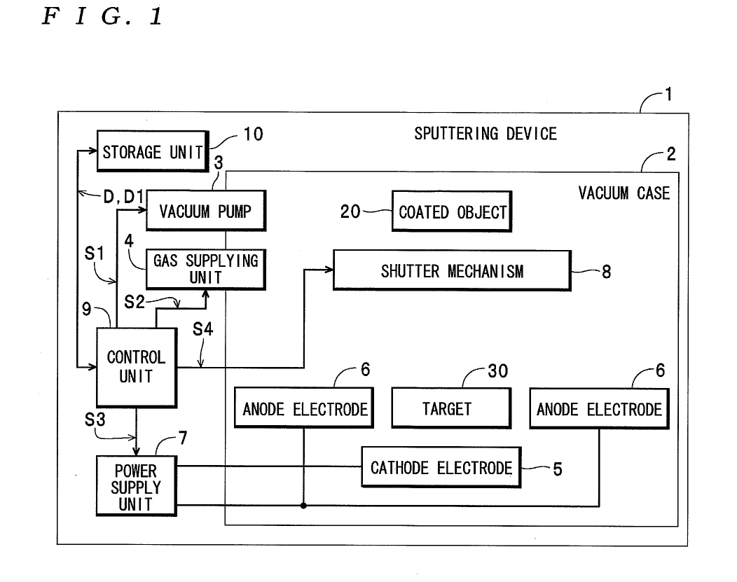

The sputtering device (a magnetron sputtering device) 1 shown in FIG. 1 is constructed so as to form various types of thin film on the surface of a coated object 20 using the thin-film forming method according to the present invention. Although there are no particular limitations on the coated object 20 on which the thin film is formed by the sputtering device 1, as examples, during the manufacturing of an information medium, a substrate used for the information medium on which various functional layers (examples of “thin films” for the present invention) used for recording and reproducing corresponds to the coated object 20, while during the manufacturing of an electronic component, magnetic head, or the like, various types of substrate such as an AlTiC substrate on which various conductive thin films (other examples of “thin films” for the present invention) are formed corresponds to the coated object 20.

The sputtering device 1 includes a vacuum case 2, a vacuum pump 3, a gas supplying unit 4, a cathode electrode 5, an anode electrode 6, a power supply unit 7, a shutter mechanism 8, a control unit 9, and a storage unit 10. The vacuum case 2 is constructed so as to be capable of housing the cathode electrode 5, the anode electrode 6, the shutter mechanism 8, the coated object 20 on which the thin film is to be formed, and a target 30 that is the material used to form the thin film. The vacuum pump 3 evacuates air from inside the vacuum case 2 in accordance with a control signal S1 from the control unit 9 to maintain a vacuum inside the vacuum case 2. The gas supplying unit 4 supplies various types of inert gas (for example, argon gas) inside the vacuum case 2 in accordance with a control signal S2 from the control unit 9.

The cathode electrode 5 and the anode electrode 6 are insulated from one another and are connected to the power supply unit 7. The power supply unit 7 applies a predetermined high-frequency voltage to the cathode electrode 5 and the anode electrode 6 in accordance with a control signal S3 from the control unit 9. The shutter mechanism 8 includes a shutter (not shown) disposed between the target 30 on the cathode electrode 5 and the coated object 20 and by opening or closing the shutter in accordance with a control signal S4 from the control unit 9, adhesion of sputter (i.e., metal particles) scattered from the target 30 to the coated object 20 is restricted (the state where the shutter is closed) or permitted (the state where the shutter is open). In the sputtering device 1, as one example, the opening and closing of the shutter of the shutter mechanism 8 each take around 0.5 to 1.0 seconds.

The control unit 9 carries out overall control of the sputtering device 1. More specifically, as described later, the control unit 9 obtains a relational expression (the “processing condition” for the present invention) showing the relationship between the processing time of the thin-film forming process (i.e., sputtering) and the thickness of the thin film using the processing condition obtaining method according to the present invention and stores the obtained equation in the storage unit 10 as “control data D” (or “control data D1”). The control unit 9 also carries out a thin-film forming process that forms a thin film (not shown) on the surface of the coated object 20 with the processing time required to form a thin film of the desired thickness (i.e., the time from when the shutter mechanism 8 starts opening the shutter to when the shutter is completely closed) set based on the control data D (or control data D1) stored in the storage unit 10.

When forming a thin film using the sputtering device 1, first the coated object 20 on which the thin film is to be formed and the target 30 (i.e., the metal material for forming the thin film) are set inside the vacuum case 2. Next, the thickness of the thin film to be formed is set by operating an operating unit, not shown. At this time, the control unit 9 calculates the processing time required to form a thin film of the desired thickness based on the control data D (or control data D1) obtained in advance as described later. After this, when a switch that designates a start of processing has been operated, the control unit 9 outputs the control signal S1 to the vacuum pump 3 to have air evacuated from the vacuum case 2 and then outputs the control signal S2 to the gas supplying unit 4 to have the inert gas supplied inside the vacuum case 2. Next, the control unit 9 outputs the control signal S3 to the power supply unit 7 to have a predetermined high-frequency voltage applied to the cathode electrode 5 and the anode electrode 6.

The inert gas inside the vacuum case 2 is ionized by the high-frequency voltage applied to the cathode electrode 5 and the anode electrode 6 and plasma is generated inside the vacuum case 2. The ions generated inside the vacuum case 2 move at high speed toward the target 30 and collide with the surface of the target 30, thereby causing metal atoms (i.e., the metal that constructs the target 30) to be knocked off and scattered as sputter toward the coated object 20. After this, the control unit 9 outputs the control signal S4 to the shutter mechanism 8 to have the shutter opened. As a result, the sputter scattered from the target 30 toward the coated object 20 adheres to the surface of the coated object 20 that has been exposed to the plasma inside the vacuum case 2.

Next, when a period equal to the processing time calculated before the start of sputtering based on the control data D (or control data D1) minus the time required by the shutter closing operation carried out by the shutter mechanism 8 has elapsed, the control unit 9 outputs the control signal S4 to the shutter mechanism 8 to have the shutter closed. Also, at substantially the same time as the closing of the shutter is completed, the control unit 9 outputs the control signal S3 to the power supply unit 7 to cause the power supply unit 7 to stop applying the high-frequency voltage to the cathode electrode 5 and the anode electrode 6. By doing so, a thin film of the desired thickness will be formed on the surface of the coated object 20 when the processing time described above has elapsed.

Next, the obtaining of a processing condition (i.e., the control data D described above) showing the relationship between the processing time of the thin-film forming process (i.e., the sputtering) and the thickness of the thin film using the processing condition obtaining method according to the present invention will be described with reference to the drawings.

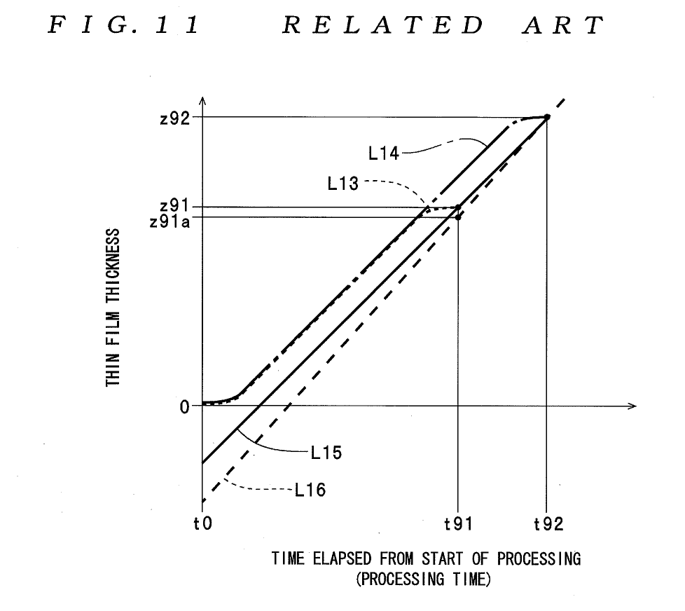

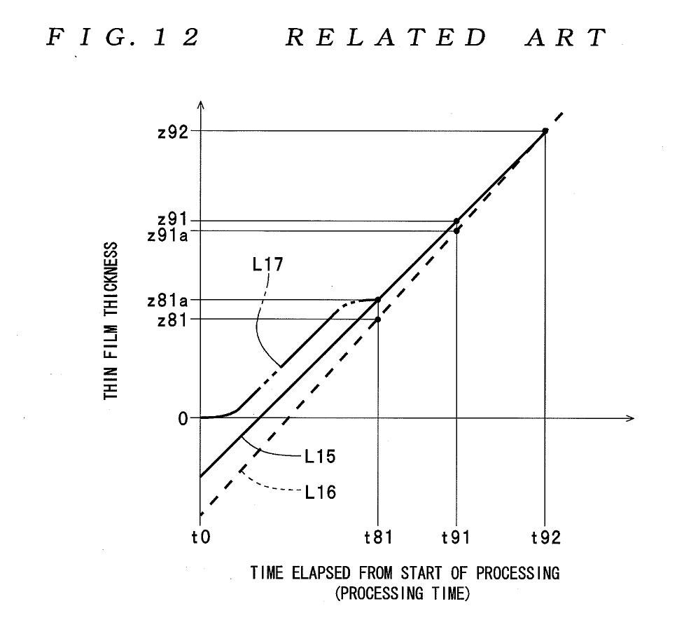

First, two coated objects 20 with the same or substantially the same size and material as the coated object 20 on which the thin film is to be formed using the processing condition obtained by the method described below are prepared. Next, an estimated processing time required to form a thin film on the surface of the coated object 20 using the processing condition obtained by this processing condition obtaining method is set. More specifically, as one example, the processing time required to form a thin film of the desired thickness is calculated based on a processing condition used when carrying out a conventional thin-film forming method (the direct function shown by the solid line L15 or the dashed line L16 in FIGS. 11 and 12) and the result of such calculation is set as the estimated processing time. When doing so, as one example, the estimated processing time is set at 60 seconds. Next, two processing times (“L seconds” and “M seconds” for the present invention) that are (i) longer than the total of the time required by the shutter mechanism 8 to open the shutter and the time required to close the shutter and (ii) in a range of 50% to 150% inclusive of the estimated processing time that has been set are set as appropriate. As one example, 30 seconds (L seconds) and 90 seconds (M seconds) are set as the two processing times. Note that the two processing times of “L seconds” and “M seconds” for the present invention should preferably be set at times that are at least ten times longer than the total of the time required to open the shutter and the time required to close the shutter.

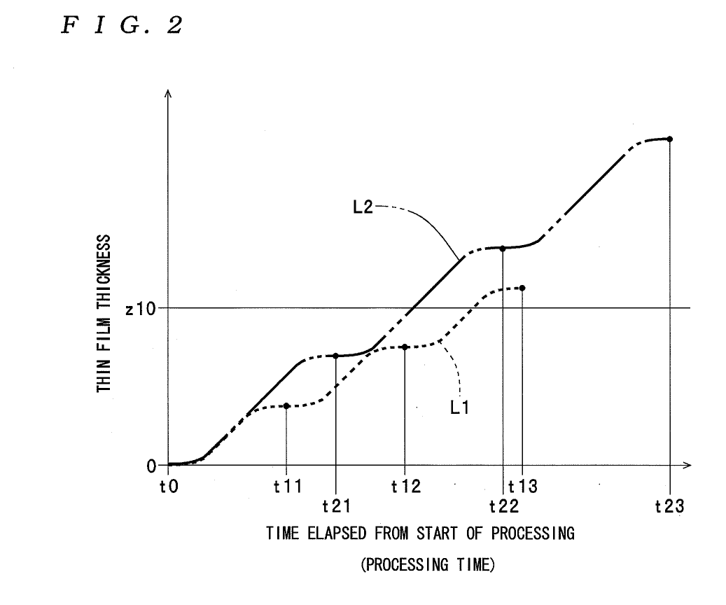

Next, one of the coated objects 20 is set inside the vacuum case 2 of the sputtering device 1 described above and one of the two processing times described above (for example, 30 seconds as L seconds) is set by operating the operating unit. After this, when an operation that designates obtaining of the processing condition has been carried out, the control unit 9 forms a thin film on the surface of the coated object 20 in the same way as the thin-film forming method described earlier. When doing so, as shown by the dotted line L1 in FIG. 2, the control unit 9 outputs the control signals S4 to the shutter mechanism 8 so that the processing time from the start time t0 of the thin-film forming process (i.e., the point where the shutter mechanism 8 starts the shutter opening operation) to the time t11 where the shutter becomes completely closed is 30 seconds and, when the time at which the first thin-film forming process has been completed (i.e., the time t11) has been reached, outputs another control signal S4 to the shutter mechanism 8 in a state where the power supply unit 7 is being caused to continue applying the high-frequency voltage to have the shutter opened (this marks the start of a second thin-film forming process). Note that in FIG. 2 and the other drawings referred to later, the time required to open and close the shutter is exaggerated relative to the total processing time of the thin-film forming process. After this, the control unit 9 outputs the control signal S4 to the shutter mechanism 8 so that the processing time from the time t11 to a time t12 where the shutter becomes completely closed is 30 seconds.

Also, when the second thin-film forming process has been completed (i.e., when the time t12 has been reached), the control unit 9 outputs the control signal S4 to the shutter mechanism 8 in a state where the power supply unit 7 is being caused to continue applying the high-frequency voltage to have the shutter opened (this marks the start of a third thin-film forming process). After this, the control unit 9 outputs the control signal S4 to the shutter mechanism 8 so that the processing time from the time t12 to a time t13 where the shutter becomes completely closed is 30 seconds. By doing so, three consecutive thin-film forming processes are completed on the coated object 20 (an example where “Na times” for the present invention is three), resulting in a thin film of the desired thickness being formed on the surface of the coated object 20. Note that although for ease of understanding the present invention, the case is described where three thin-film forming processes are carried out as one example of “Na times” for the present invention, the present invention is not limited to this. More specifically, the purpose of carrying out the thin-film forming process multiple times is to produce a thin film whose thickness is sufficient to allow correct measurement, and as one example it is preferable to carry out the thin-film forming process around twenty to thirty times to form a thin film (or a laminated structure of multiple thin films) whose thickness can be correctly measured. Here, an example will be described where the minimum thickness that can be measured correctly is “z10” and “Na times” is set at three times which is the minimum number of thin-film forming processes that can form a thin film (or laminated structure) that is thicker than z10.

Next, the coated object 20 for which the formation of thin films has been completed is removed from the vacuum case 2, the other coated object 20 is set inside the vacuum case 2, and the other of the two processing times described above (for example, 90 seconds as M seconds) is set by operating the operating unit. After this, when an operation that designates the obtaining of the processing condition has been carried out, the control unit 9 forms a thin film on the surface of the coated object 20 in the same way as the thin-film forming method described earlier. When doing so, as shown by the dot-dot-dash line L2 in FIG. 2, the control unit 9 outputs the control signals S4 to the shutter mechanism 8 so that the processing time from the start time t0 of the thin-film forming process (i.e., the point where the shutter mechanism 8 starts the shutter opening operation) to the time t21 where the shutter becomes completely closed is 90 seconds. Note that in FIG. 2, for ease of understanding the present invention, the period from t0 to t21 is shown using a different (i.e., reduced) scale on the time axis to the period from t0 to t11. Also, when the first thin-film forming process has been completed (i.e., when the time t21 is reached), the control unit 9 outputs the control signal S4 to the shutter mechanism 8 in a state where the power supply unit 7 is being caused to continue applying the high-frequency voltage to start a second thin-film forming process.

After this, the control unit 9 outputs the control signal S4 to the shutter mechanism 8 so that the processing time from the time t21 to a time t22 where the shutter becomes completely closed is 90 seconds. Also, when the second thin-film forming process has been completed (i.e., when the time t22 is reached), the control unit 9 outputs the control signal S4 to the shutter mechanism 8 in a state where the power supply unit 7 is being caused to continue applying the high-frequency voltage to start a third thin-film forming process. After this, the control unit 9 outputs the control signal S4 to the shutter mechanism 8 so that the processing time from the time t22 to a time t23 where the shutter becomes completely closed is 90 seconds. By doing so, three consecutive thin-film forming processes are completed on the coated object 20 (an example where “Nb times” for the present invention is three), resulting in a thin film of the desired thickness being formed on the surface of the coated object 20. Note that although the case where three thin-film forming processes are carried out as one example of “Nb times” for the present invention has been described for ease of understanding, in the same way as “Na times” described above, the present invention is not limited to this and it is possible to carry out the thin-film forming process a freely chosen number of times that can produce a thin film whose thickness is sufficient to allow correct measurement. When doing so, “Na times” and “Nb times” for the present invention are not limited to being the same number and can be set at different numbers.

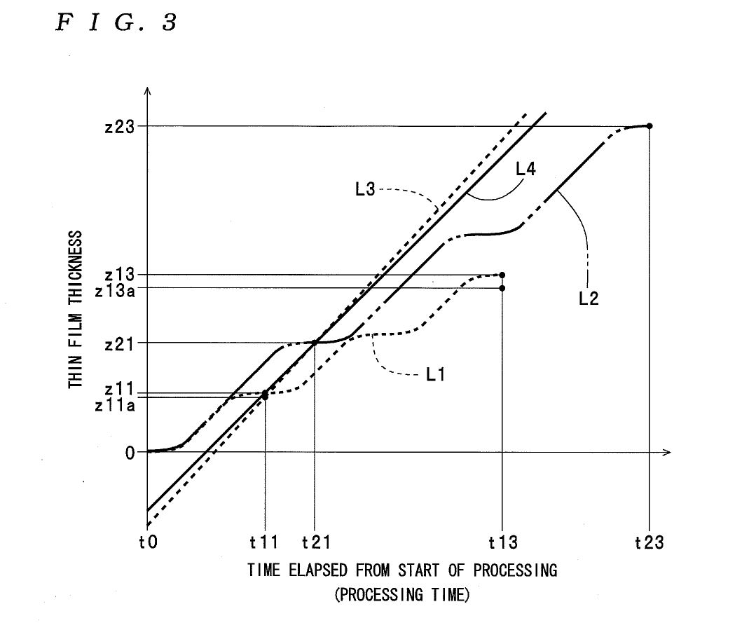

Next, the thickness of the thin film formed by consecutively carrying out three 30-second thin-film forming processes and the thickness of the thin film formed by consecutively carrying out three 90-second thin-film forming processes are measured using a fluorescent x-ray analyzer, for example. When doing so, as shown in FIG. 3, as one example, assume that the thickness z13a (an example where a measurement error has occurred with respect to the actual thickness z13) of the thin film formed by carrying out three thin-film forming processes between the time t0 and the time t13 and the thickness z23 (an example where no measurement error has occurred with respect to the actual thickness z13) of the thin film formed by carrying out three thin-film forming processes between the time t0 and the time t23 have been measured. After this, the measured thicknesses z13a, z23 of the two thin films used to obtain the processing condition are divided by the number of processes carried out when forming the respective thin films (“Na times” and “Nb times” for the present invention: in this example, both three). By doing so, the thicknesses of the parts formed by single thin-film forming processes during the formation of such thin films (i.e., the part formed in L seconds (=30 seconds) and the part formed in M seconds (=90 seconds)) are calculated. This results in the thicknesses z11a, z21 in FIG. 3 being calculated.

Next, as one example, by operating the operating unit, the calculation results (i.e., the thicknesses z11a and z21) are inputted into the sputtering device 1. At this point, the control unit 9 calculates a processing condition that shows the relationship between the processing time of the thin-film forming process carried out by the sputtering device 1 and the thickness of the thin film, based on the inputted thicknesses z11a and z21 and the processing times (in this example, L seconds=30 and M seconds=90) required to form thin films of the thicknesses z11a and z21. As one example, the direct function shown by the dashed line L3 in FIG. 3 (i.e., a relational expression that shows the relationship between the processing time and the thickness of the thin film) is calculated. Next, the control unit 9 stores the calculated processing condition in the storage unit 10 as the control data D. By doing so, the obtaining of a processing condition using the processing condition obtaining method according to the present invention is completed.

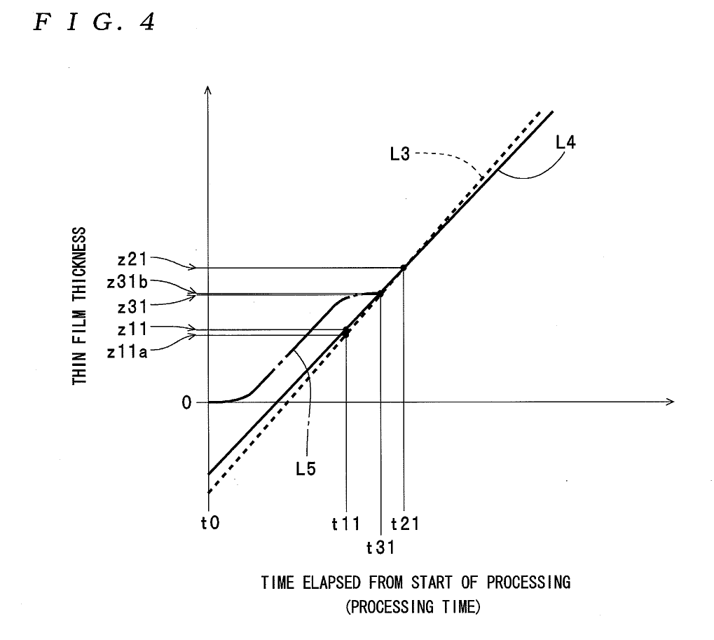

By setting the processing time based on the processing condition (i.e., the control data D) obtained by the method described above, it is possible to form a thin film of the desired thickness, even if the thickness is minute. More specifically, as shown in FIG. 4, when an input operation that inputs the thickness z31 as a desired thickness has been carried out via an input operation of the operating unit, the control unit 9 calculates the processing time (in this example, the period from the time t0 to the time t31) required to form a thin film of the thickness z31 based on the processing condition described above (the control data D: the direct function shown by the dashed line L3 in FIG. 3) that has been stored in the storage unit 10. Here, as shown in FIG. 3, the control data D (the processing condition) stored in the storage unit 10 was calculated based on the thickness z13a for which a measurement error occurred and the thickness z23 for which no measurement error occurred. On the other hand, if, during the process that obtains the processing condition described earlier, the thickness of the thin film produced by carrying out a 30-second thin-film forming process three times had been correctly measured as the thickness z13, the thickness of the part formed by one execution of the thin-film forming process (i.e., the part formed in L seconds (=30 seconds)) would be calculated as the thickness z11 and the direct function shown by the solid line L4 in FIG. 3 would be calculated as the processing condition (i.e., the control data D).

After this, when a switch that designates the start of processing has been operated, the control unit 9 controls the vacuum pump 3 to evacuate the air inside the vacuum case 2 and controls the gas supplying unit 4 to supply the inert gas inside the vacuum case 2. Next, the control unit 9 outputs the control signal S3 to the power supply unit 7 to apply the predetermined high-frequency voltage to the cathode electrode 5 and the anode electrode 6. As a result, ions generated inside the vacuum case 2 move at high speed toward the target 30 and collide with the surface of the target 30, thereby causing metal atoms to be knocked off and scattered as sputter toward the coated object 20. After this, the control unit 9 outputs the control signal S4 to the shutter mechanism 8 to open the shutter and at a time t31 when the processing time calculated based on the control data D inside the storage unit 10 has elapsed, outputs another control signal S4 to the shutter mechanism 8 to close the shutter. By doing so, the thin-film forming process is completed as shown by the dot-dash line L5 in FIG. 4, thereby forming a thin film with the thickness z31 on the surface of the coated object 20.

Here, the control data D (the processing condition) used during the thin-film forming process described above was obtained based on the thickness z11a found by dividing the thickness z13a by the number of processes (in this example, three times) during the obtaining process. This means that the error between the actual thickness z13 of the thin film formed by the three thin-film forming processes and the thickness z13a for which a measurement error has occurred is reduced to the reciprocal of the number of processes (i.e., 1/Na: ⅓ in this example). Accordingly, the error between the actual processing condition (the processing condition shown by the solid line L4 in FIG. 4) and the processing condition that has been actually obtained (the control data D: the processing condition shown by the dashed line L3 in FIG. 4) is sufficiently reduced. This means that by carrying out the thin-film forming process from the time t0 to the time t31, although a thin film is actually formed with the thickness z31b that is slightly thicker than the thickness z31, the error between the thickness z31 and the thickness z31b is extremely small.

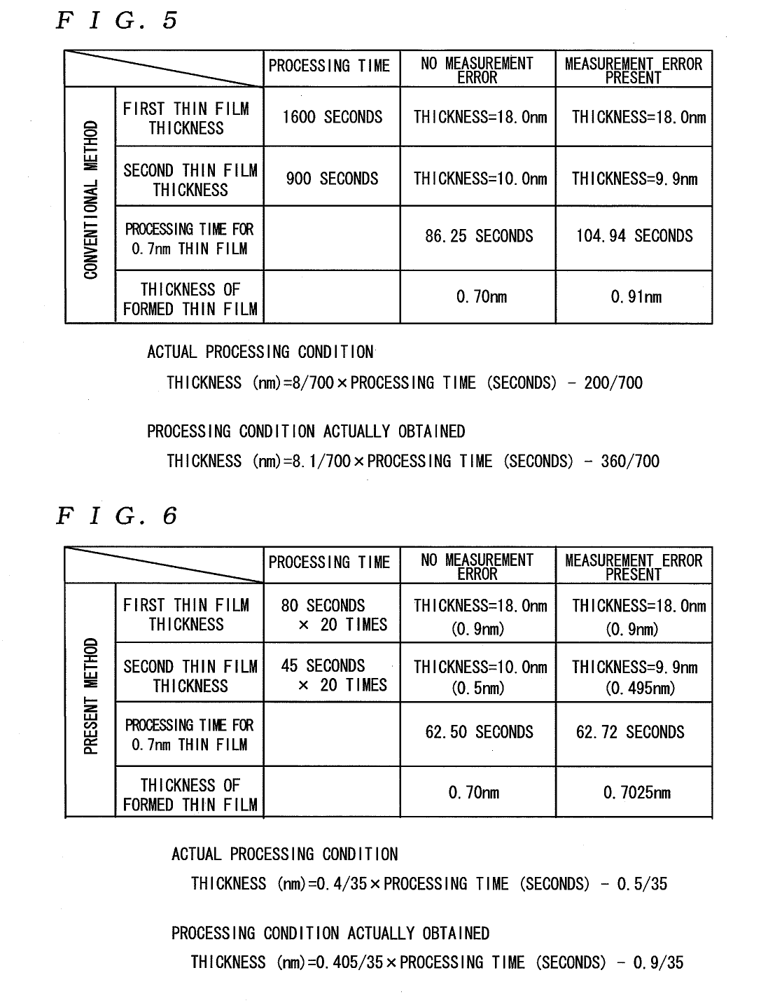

More specifically, it was confirmed that the following errors occur when obtaining a processing condition used when forming a thin film with a thickness of around 0.7 nm during the manufacturing of a composite magnetic head, for example, using a processing condition obtaining method in a conventional thin-film forming method and the processing condition obtaining method according to the present invention. First, as shown in FIG. 5, according to the conventional processing condition obtaining method, two thin films are manufactured by the sputtering device 1 described above with the thin-film forming process for the first thin film set at 1600 seconds and the thin-film forming process for the second thin film set at 900 seconds. When doing so, as one example, assume that the thickness of the first thin film is 18.0 nm and the thickness of the second thin film is 10.0 nm, and that when the processing condition is obtained, a measurement error of 1% occurs for the measured value of thickness for the second thin film only, which is measured at 9.9 nm. Here, as shown in FIG. 5, the processing condition that is actually obtained is a relational expression that differs to the actual processing condition. Accordingly, if the processing time is set based on the obtained processing condition, even though the processing time required to form a thin film of 0.7 nm is actually 86.25 seconds, the processing time will be set at 104.94 seconds. This means that even though a thin film is to be formed with a thickness of 0.7 nm, a thin film is formed with a thickness of 0.91 nm.

On the other hand, as shown in FIG. 6, when two thin films are manufactured using the sputtering device 1 described above using the processing condition obtaining method according to the present invention by carrying out the thin-film forming process for the first thin film as twenty 80-second processes and the thin-film forming process for the second thin film as twenty 45-second processes, as one example, the thickness of the first thin film is 18.0 nm and the thickness of the second thin film is 10.0 nm. Note that in this example, to make the thicknesses equal to those of the thin films formed when conventionally obtaining the processing condition, various conditions (such as the voltage of the high-frequency voltage applied to the cathode electrode 5 and the anode electrode 6) differ to the conventional method. When doing so, assume that a measurement error of 1% occurs when measuring the thickness for the second thin film only, which is measured at 9.9 nm. Here, as shown in FIG. 6, the processing condition actually obtained will be a relational expression that differs to the actual processing condition. Accordingly, if the processing time is set based on the obtained processing condition, even though the processing time required to form a thin film of 0.7 nm is actually 62.50 seconds, the processing time will be set slightly longer than such processing time at 62.72 seconds. However, when a thin-film forming process is actually carried out for such processing time, the thickness of the formed thin film is 0.7025 nm, which is substantially equal to the desired thickness of 0.7 nm. Accordingly, for a composite head manufactured by laminating extremely thin films, the finished dimensions can sufficiently approach the designed dimensions and it becomes possible to manufacture a composite magnetic head with the desired recording/reproducing characteristics.

In this way, with the processing condition obtaining method described above, the thickness Ta (the thickness z13a) of a thin film formed by carrying out the thin-film forming process with a processing time set at L seconds (in this example, 30 seconds) Na times (in this example, three times) is measured, the thickness Tb (the thickness z23) of a thin film formed by carrying out the thin-film forming process with a processing time set at M seconds (in this example, 90 seconds) Nb times (in this example, three times) is measured, and a processing condition is obtained with the thickness of a thin film formed by a thin-film forming process with a processing time set at L seconds (that is, the thickness of a thin film after L seconds have elapsed from the start of the thin-film forming process) as Ta/Na and the thickness of a thin film formed by a thin-film forming process with a processing time set at M seconds (that is, the thickness of a thin film after M seconds have elapsed from the start of the thin-film forming process) as Tb/Nb. By doing so, it is possible to obtain the processing condition based on measured values (thicknesses) of relatively thick films that have been formed by carrying out the thin-film forming process multiple times. Accordingly, it is possible to sufficiently raise the measurement precision compared to a processing condition obtained based on measured values (i.e., thicknesses) of very thin films whose thicknesses are difficult to measure correctly. Also, even if a measurement error occurs for a measured value of the thickness when the processing condition is obtained, since the processing condition is obtained based on a value where the measurement error is reduced to the reciprocal of the number of processes (1/Na times, 1/Nb times: in this example both ⅓), it is possible to sufficiently increase the precision. As a result, it is possible to form even an extremely thin film with the desired thickness.

In this case, it is preferable to set the respective lengths of L seconds and M seconds in a range of 50% to 150% inclusive of the estimated processing time required to form a thin film of the desired thickness. By setting the respective lengths of L seconds and M seconds for the present invention so as to satisfy this condition, compared to when the processing condition is obtained with the respective lengths of L seconds and M seconds set at below 50% or over 150% of the estimated processing time, it is possible to obtain the processing condition based on the measured value (i.e., thickness) for a laminated structure of thin films formed with a similar processing time to the processing time used when actually forming a thin film. As a result, it is possible to obtain the processing condition with significantly higher precision in line with an actual thin-film forming process.

Also, according to the thin-film forming method that uses the sputtering device 1, by forming thin films by carrying out the L-second thin-film forming process and the M-second thin-film forming process an equal number of times, unlike for example a method that obtains the processing condition based on the thickness Ta of a thin film formed by carrying out the L-second thin-film forming process three times (an example where “Na=3”) and on the thickness Tb of a thin film formed by carrying out the M-second thin-film forming process three hundred times (an example where “Nb=300”), or in other words unlike a method where Na and Nb differ, it is possible to avoid a situation where one of the two thin films is formed excessively thinly or where one film is formed excessively thickly and to produce both thin films with thicknesses that can be measured with the same measurement environment (i.e., the same measurement apparatus). Accordingly, it is possible to avoid a situation where measurement errors occur due to differences in the measurement environment and therefore it is possible to obtain the processing condition with sufficiently high precision.

Also, according to the processing condition obtaining method described above, the respective lengths of L seconds and M seconds for the present invention are both set longer than the total of the time required by the shutter mechanism 8 of the sputtering device 1 to open and the time required to close. Accordingly, it is possible to avoid a situation where thin-film forming processes are carried out a plurality of times for an extremely short time where the closing operation of the shutter starts before the shutter becomes completely open, and therefore it is possible to obtain the processing condition with high precision that is in line with an actual thin-film forming process.

Also, according to the thin-film forming method that uses the sputtering device 1 described above, by forming a thin film with a processing time set based on the processing condition (i.e., control data D) obtained by one of the processing condition obtaining methods described above, it is possible to set the processing time based on a processing condition with sufficiently high precision. As a result, it is possible to form even an extremely thin film with the desired thickness.

Next, the obtaining of a processing condition (the control data D described above) showing the relationship between the processing time of a thin-film forming process (i.e., sputtering) and the thickness of a thin film according to another processing condition obtaining method of the present invention will be described with reference to the attached drawings. Note that component elements that are the same as in the processing condition obtaining method described above have been assigned the same reference numerals and duplicated description thereof is omitted.

In view of the effect of changes over time and the like on a thin-film forming apparatus, the processing condition (the control data D) obtained by the processing condition obtaining method described earlier or the like should preferably be updated at intervals of a fixed period (i.e., a new processing condition should be regularly obtained). Since it is necessary to form two thin films (i.e., the thin film formed by carrying out the L-second thin-film forming process Na times and the thin film formed by carrying out the M-second thin-film forming process Nb times) when updating the processing condition (the control data D) according to the processing condition obtaining method described earlier, there is the risk of the time required to carry out the updating process for the processing condition taking a short but still significant time. For this reason, the applicant has found a processing condition obtaining method that can reduce the time required to update the processing condition while still applying the fundamental concept of the processing condition obtaining method described earlier. More specifically, if a base value for a given thin-film forming apparatus is found in advance by forming two thin films according to the processing condition obtaining method described earlier, whenever the updating process for the processing condition is carried out thereafter, by merely forming one thin film, it will be possible to obtain a processing condition with a similar precision to the processing condition obtaining method described earlier. This obtaining method is described in detail below.

First, two coated objects 20 are prepared in the same way as the processing condition obtaining method described above. Next, the estimated processing time required to form a thin film (as one example, 60 seconds) is set for the thin film to be formed on the surface of the coated objects 20 using the processing condition obtained by such processing condition obtaining method. Next, two processing times (“L seconds” and “M seconds” for the present invention) that are (i) longer than the total of the time required by the shutter mechanism 8 to open the shutter and the time required to close the shutter and (ii) in a range of 50% to 150% inclusive of the estimated processing time that has been set are set as appropriate. As one example, 30 seconds (L seconds) and 90 seconds (M seconds) are set as the two processing times. Next, in the same way as the processing condition obtaining method described earlier, one of the coated objects 20 is set inside the vacuum case 2 of the sputtering device 1 described above and as shown by the dotted line L1 in FIG. 2, a thin-film forming process that is 30 seconds long (corresponding to L seconds for the present invention) is carried out consecutively three times (an example where “Na times” for the present invention is three) to form a thin film of a predetermined thickness on the surface of the coated object 20. Next, after the coated object 20 for which the formation of the thin film has been completed has been taken out of the vacuum case 2, the other of the coated objects 20 is set inside the vacuum case 2 and as shown by the dot-dot-dash line L2 in FIG. 2, a thin-film forming process that is 90 seconds long (corresponding to M seconds for the present invention) is carried out consecutively three times (an example where “Nb times” for the present invention is three, which is equal to Na) to form a thin film of a predetermined thickness on the surface of the coated object 20.

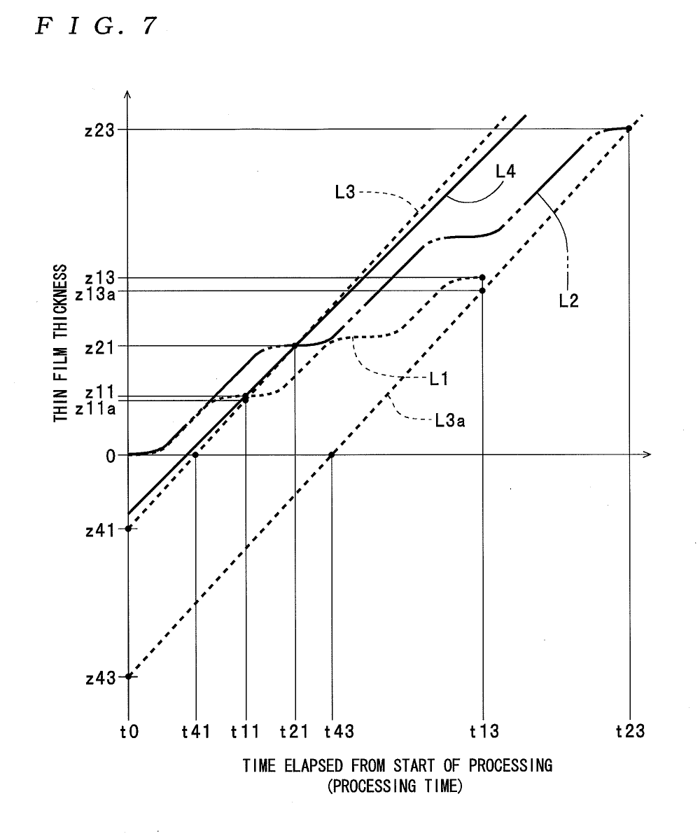

After this, the thickness of the thin film formed by consecutively carrying out three 30-second thin-film forming processes and the thickness of the thin film formed by consecutively carrying out three 90-second thin-film forming processes are measured. When doing so, as shown in FIG. 7, as one example, assume that the thickness z13a (an example where a measurement error has occurred with respect to the actual thickness z13) is measured for the thin film formed by carrying out three (=Na) 30-second (=L-second) thin-film forming processes between the time t0 and the time t13 and the thickness z23 (an example where no measurement error has occurred with respect to the actual thickness z13) is measured for the thin film formed by carrying out three (=Nb) 90-second (=M-second) thin-film forming processes between the time t0 and the time t23. After this, the measured thicknesses z13a, z23 of the two thin films used to obtain the processing condition are divided by the number of processes carried out when forming the respective thin films (“Na times” and “Nb times” for the present invention: in this example, both three). By doing so, the thicknesses of the parts formed by single thin-film forming processes during the formation of such thin films (i.e., the part formed in L seconds (=30 seconds) and the part formed in M seconds (=90 seconds)) are calculated. This results in the thicknesses z11a, z21 in FIG. 3 being calculated.

Next, as one example, by operating the operating unit, the calculation results (i.e., the thicknesses z11a and z21) are inputted into the sputtering device 1. At this point, the control unit 9 calculates a direct function (a relational expression showing the relationship between the processing time and the thickness of the thin film) shown by the dashed line L3 in FIG. 7, based on the inputted thicknesses z11a and z21 and the processing times (in this example, L seconds=30 and M seconds=90) required to form thin films of the thicknesses z11a and z21. Next, by substituting a predetermined thickness Tx (as one example, a thickness of zero) set in advance into the calculated direct function, the control unit 9 calculates a processing time of X seconds required to form a thin film of the thickness Tx according to a thin-film forming process that uses this sputtering apparatus and stores such processing time in the storage unit 10. Here, although the actual time required to form a thin film with a thickness of zero is zero seconds, by substituting “thickness zero” into the direct function described above, the time corresponding to time t0 to t41 is calculated as the processing time X.

Note that by substituting an arbitrary thickness (the “thickness Tx” for the present invention: for example, 5 nm) into the direct function described above in place of the thickness of zero, it is possible to calculate the processing time X required to form a thin film of the arbitrary thickness and store the processing time of X seconds in the storage unit 10. The method that finds X seconds that is the processing time required to form a thin film of thickness zero, for example, is not limited to a method that uses the direct function shown by the dashed line L3 described above. As one example, it is also possible to use a method that finds the direct function shown by the dashed line L3a in FIG. 7 based on the thickness z13a of the thin film formed by carrying out the 30-second thin-film forming process consecutively three times and on the thickness z23 of the thin film formed by carrying out the 90-second thin-film forming process consecutively three times, substitutes an arbitrary thickness Tx into this direct function to calculate a predetermined time (in this example the time t0 to t43), and divides the calculation result by the number of processing iterations (in this example, Na=Nb=3) to find the time (time t0 to t41) corresponding to X seconds described above.

Here, X seconds (time t0 to t41) described above corresponds to a delay time caused by a fall in the formation rate of the thin film (i.e., the amount of thin film formed per unit processing time) due to the opening and closing of the shutter mechanism 8 of the sputtering device 1. This delay time does not vary for the same sputtering device 1 and is a period with a substantially constant length. This means that even if the sputtering device 1 is operated on a different day, for example, to the day when the thin films of the thicknesses z13a, z23 described above were formed, X seconds that is the processing time required to form a thin film of thickness zero (the time corresponding to time t0 to t41 in FIG. 7) will not vary and will be a period of substantially the same length as the X seconds given above. Accordingly, as described above, by obtaining in advance the processing time of X seconds described above which is required to form a thin film of thickness zero, for example, it is possible when subsequently obtaining the processing condition for the present invention to obtain the processing condition by forming and measuring the thickness of only one thin film without having to form and measure the thickness of two thin films like the processing condition obtaining method described above.

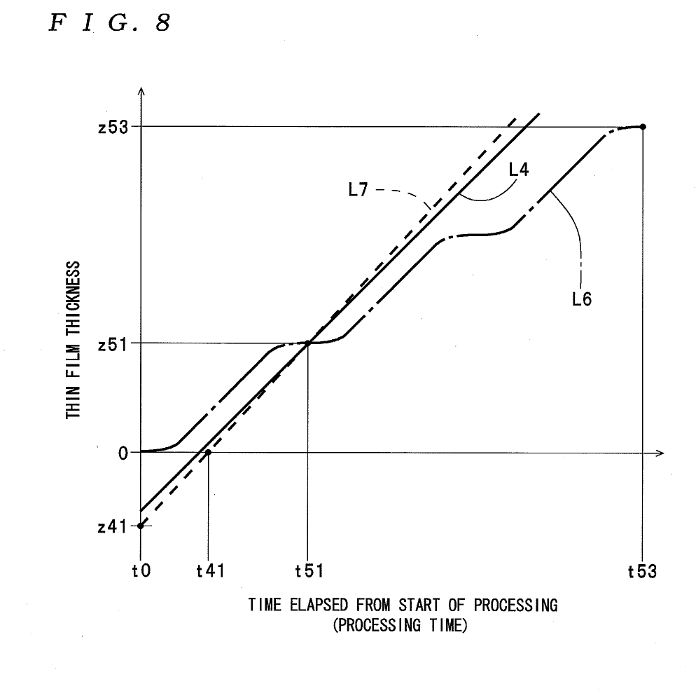

More specifically, first, a coated object 20 that is the same as the coated object 20 described above is prepared. Next, the estimated processing time (as one example, 60 seconds) required to form a thin film is set in the same way as when setting L seconds (30 seconds) and M seconds (90 seconds) described above. After this, a processing time (“K seconds” for the present invention) that is in a range of 50% to 150% inclusive of the set estimated processing time and is longer than the total of the time required by the shutter mechanism 8 to open the shutter and close the shutter is set as appropriate. When doing so, as one example, the processing time is set at 90 seconds, which is equal to M seconds described above. Next, the coated object 20 is set inside the vacuum case 2 of the sputtering device 1 described above and a thin-film forming process that is 90 seconds long (corresponding to “K seconds” for the present invention) is carried out three times (one example, where “Nc times” for the present invention is three) consecutively to form a thin film of a predetermined thickness on the surface of the coated object 20. After this, the thickness of the thin film formed by consecutively carrying out three 90-second thin-film forming processes is measured. Here, as shown in FIG. 8, as one example, the thickness of the thin film formed by carrying out the 90-second (“K-second”) thin-film forming process between time t0 and t53 consecutively three times (“Nc” times) is measured as “thickness z53”. Next, the measured thickness z53 is divided by the number of times the thin-film forming process was carried out when forming the thin film (“Nc times” for the present invention: in this example three). By doing so, the thickness of the part formed by one thin-film forming process during the formation of the thin film (i.e., the thickness of the part formed in K seconds=the 90 seconds from time t0 to t51) is calculated. When doing so, the thickness z51 in FIG. 8 is calculated.

Next, as one example, by operating the operating unit, the calculation result (i.e., the thickness z51) described above is inputted into the sputtering device 1. When doing so, based on information on the inputted thickness z51, the processing time (in this example, K seconds=90 seconds) required to form a thin film of the thickness z51, and the processing time of X seconds required to form a thin film of thickness zero (in this example, time t0 to t41), the control unit 9 calculates the direct function (the relational expression showing the relationship between the processing time and the thickness of the thin film) shown by the dashed line L7 in FIG. 8 with the thickness of the thin film formed by a thin-film forming process with the processing time set at K seconds as Tc/Nc (in this example, the thickness z51) and the thickness of the thin film formed by a thin-film forming process with the processing time set at X seconds as Tx (in this example, the thickness zero) After this, the control unit 9 stores the calculated processing condition in the storage unit 10 as the control data D1. By doing so, the obtaining of the processing condition by the processing condition obtaining method according to the present invention is completed.

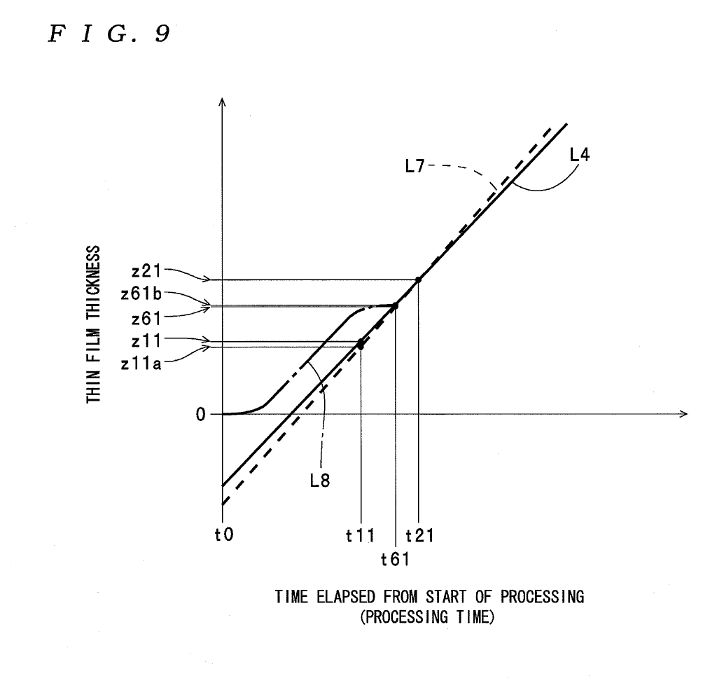

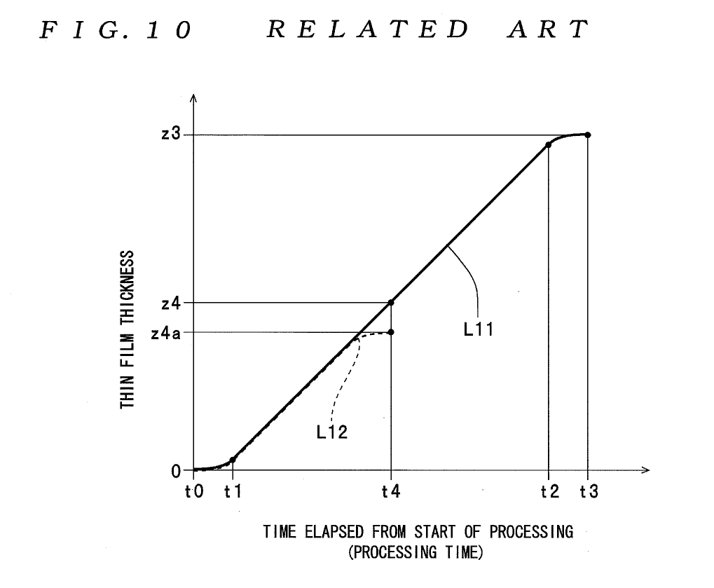

By setting the processing time based on the processing condition (the control data D1) obtained by the method described above, it is possible to form a thin film of the desired thickness, even a minute thickness for example, in the same way as when the processing time is set based on the processing condition (control data D) obtained by the processing condition obtaining method described earlier. More specifically, as shown in FIG. 9, when a thickness z61 is inputted as the desired thickness by carrying out an input operation of the operation unit, the control unit 9 calculates the processing time (in this example, the period from time t0 to time t61) required to form a thin film of the thickness z61 based on the processing condition (the control data D1: the direct function shown by the dashed line L7 in FIG. 9) described above that has been stored in the storage unit 10. Next, when a switch that designates the start of processing is operated, the control unit 9 controls the vacuum pump 3 to discharge air inside the vacuum case 2 and controls the gas supplying unit 4 to supply inert gas inside the vacuum case 2. Next, by outputting the control signal S3 to the power supply unit 7, the control unit 9 has a predetermined high frequency voltage applied between the cathode electrode 5 and the anode electrode 6. Since the ions generated inside the vacuum case 2 as a result move at high speed toward the target 30 and collide with the surface of the target 30, the metal ions are knocked off and dispersed as sputter toward the coated object 20. Next, the control unit 9 controls the shutter mechanism 8 to open the shutter and, at the time t61 when the processing time calculated based on the control data D1 in the storage unit 10 has elapsed, outputs a control signal S4 to the shutter mechanism 8 to close the shutter. By doing so, the thin-film forming process is completed as shown by the dot-dash line L8 in FIG. 9, and a thin film of the thickness z61 is formed on the surface of the coated object 20.

Here, the control data D1 (processing condition) used in the thin-film forming process described above has been obtained using a direct function (in this example, the direct function shown by the dashed line L7 in FIG. 8) calculated based on the thickness z11a found by dividing the thickness z13a of the thin film formed by carrying out the thin-film forming process Na times (in this example, three times) by the number of processes (in this example, Na=three) when obtaining the processing condition. This means that by using a direct function calculated based on the thickness z11a where the difference between the actual thickness z13 of the thin film and the thickness z13a for which a measurement error has occurred is reduced to 1/number of processes (in this example, ⅓), the control data D1 (processing condition) is sufficiently accurate. Also, the control data D1 (i.e., the processing condition) is obtained based on the thickness (in this example, the thickness z51) of “a thin film formed by carrying out the thin-film forming process with the processing time set at K seconds” which is produced by dividing the thickness z53 of a thin film formed by Nc (in this example, three) thin-film forming processes by the number of processes (here, Nc=three). This means that even if a measurement error occurs for the thickness z53 of the thin film formed by three thin-film forming processes, the processing condition will be obtained based on the thickness z51 where the difference between the real thickness and the actual thickness z53 is reduced to 1/number of processes (1/Nc: in this example, ⅓), and therefore the control data D1 (processing condition) can be made sufficiently accurate. Accordingly, the difference between the real processing condition (the processing condition shown by the solid line L4 in FIGS. 8 and 9) and the processing condition that is actually obtained (the control data D1: the processing condition shown by the dashed line L7 in FIGS. 8 and 9) can be sufficiently reduced. By doing so, as shown in FIG. 9, although a thin film with a thickness z61b that is slightly thicker than the thickness z61 is formed by carrying out the thin-film forming process from time t0 to t61, the difference between the thickness z61 and the thickness z61b is extremely small.

In this way, according to the processing condition obtaining method described above, the thickness Ta (the thickness z13a) of the thin film formed by carrying out the thin-film forming process with a processing time set at L seconds (as one example, 30 seconds) Na (in this example, three) times and the thickness Tb (the thickness z23) of the thin film formed by carrying out the thin-film forming process with a processing time set at M seconds (as one example, 90 seconds) Nb (in this example, three) times are measured. The processing time X required to form a thin film with a predetermined thickness Tx (in this example, the thickness zero) is found with the thickness of the thin film formed by the thin-film forming process with the processing time set at L seconds (that is, the thickness of the thin film at a point L seconds from the start of the thin-film forming process) as Ta/Na and the thickness of the thin film formed by the thin-film forming process with the processing time set at M seconds (that is, the thickness of the thin film at a point M seconds from the start of the thin-film forming process) as Tb/Nb. After this, the thickness Tc (thickness z53) of the thin film formed by carrying out the thin-film forming process with the processing time set at K seconds (as one example, 90 seconds) Nc times (in this example, three times) is measured, and a processing condition is obtained with the thickness of the thin film formed by a thin-film forming process with the processing time set at K seconds (that is, the thickness of the thin film at a point K seconds from the start of the thin-film forming process) as Tc/Nc and the thickness of the thin film formed by a thin-film forming process with the processing time set at X seconds (that is, the thickness of the thin film at a point X seconds after the start of processing) as Tx.

By doing so, according to this processing condition obtaining method, it is possible to obtain a processing condition based on a measured value (i.e., thickness) of a relatively thick film formed by carrying out the thin-film forming process multiple times. Accordingly, it is possible to sufficiently raise the precision of the processing condition compared to a processing condition obtained based on a measured value (i.e., thickness) of a thin film whose thickness is difficult to measure accurately. Even if a measurement error does occur for a measured value of thickness when obtaining a processing condition, the processing condition will be obtained based on a value where the measurement error is reduced to the reciprocal of the number of processes (i.e., 1/Na, 1/Nb, and 1/Nc, all ⅓ in this example), and therefore the precision of the processing condition can be sufficiently increased. As a result, it is possible to form even an extremely thin film with the desired thickness. In addition, by finding the processing time of X seconds required to form a thin film of a predetermined thickness Tx (in this example, the thickness zero) in advance, when subsequently obtaining the processing condition (i.e., the control data D1), by merely measuring the thickness Tc of a thin film formed by carrying out the thin-film forming process with a processing time set at K seconds (in this example, 90 seconds) Nc times (in this example three times), it is possible to obtain the control data D1 corresponding to the “processing condition” for the present invention with the thickness of a thin film formed by carrying out the thin-film forming process with the processing time set at K seconds as Tc/Nc and the thickness of a thin film formed by the thin-film forming process with the processing time set at X seconds as Tx. Accordingly, compared to a processing condition obtaining method that measures the thickness Ta of a thin film formed by carrying out the thin-film forming process with the processing time set at L seconds (for example, 30 seconds) Na times (for example, three times) and measures the thickness Tb of a thin film formed by carrying out the thin-film forming process with the processing time set at M seconds (for example, 90 seconds) Nb times (for example, three times) every time the processing condition is obtained, when obtaining the processing condition for the second and subsequent times, it is sufficient to form one thin film by carrying out the thin-film forming process with the processing time set at K seconds (for example, 90 seconds) Nc times (for example, three times), and therefore the processing condition (i.e., the control data D1) can be obtained in a short time.

Also, according to the thin-film forming method that uses the sputtering device 1, by forming thin films by carrying out the L-second thin-film forming process for the present invention, the M-second thin-film forming process for the present invention, and the K-second thin-film forming process for the present invention an equal number of times, unlike for example a method that obtains the processing condition based on the thickness Ta of a thin film formed by carrying out the L-second thin-film forming process three times (an example where “Na=3”) and on the thickness Tb of a thin film formed by carrying out the M-second thin-film forming process three hundred times (an example where “Nb=300”), or in other words unlike a method where Na and Nb differ, it is possible to avoid a situation where one of the two thin films is formed excessively thinly or where one film is formed excessively thickly and to produce both thin films with thicknesses that can be measured with the same measurement environment (i.e., the same measurement apparatus). Accordingly, it is possible to avoid a situation where measurement errors occur due to differences in the measurement environment and therefore it is possible to obtain a calculation result (in this example, the direct function) with sufficiently high precision. Also, compared to a case where Nc times for the present invention differs to Na times and Nb times for the present invention, it is possible to avoid a situation where one of the thin films is formed excessively thinly or where one film is formed excessively thickly and to produce all of the thin films with thicknesses that can be measured with the same measurement environment (i.e., the same measurement apparatus). Accordingly, it is possible to avoid a situation where measurement errors occur due to differences in the measurement environment and therefore it is possible to obtain the processing condition with sufficiently high precision.

Also, according to the processing condition obtaining method described above, the respective lengths of L seconds, M seconds, and K seconds for the present invention are all set longer than the total of the time required by the shutter mechanism 8 of the sputtering device 1 to open and close. Accordingly, it is possible to avoid a situation where thin-film forming processes are carried out a plurality of times for an extremely short time where the closing operation of the shutter starts before the shutter becomes completely open, and therefore it is possible to obtain the processing condition with high precision that is in line with an actual thin-film forming process.

Also, according to the thin-film forming method that uses the sputtering device 1 described above, by forming a thin film with a processing time set based on the processing condition (i.e., control data D) obtained by one of the processing condition obtaining methods described above, it is possible to set the processing time based on a processing condition with sufficiently high precision. As a result, it is possible to form even an extremely thin film with the desired thickness.

Note that the present invention is not limited to the construction and method described above. For example, although an example has been described where each process out of the Na thin-film forming processes for the present invention starts as soon as a preceding process has been completed (i.e., where the Na thin-film forming processes are carried out consecutively) and where each process out of the Nb thin-film forming processes for the present invention starts as soon as a preceding process has been completed (i.e., where the Nb thin-film forming processes are carried out consecutively), it is also possible to use a method where a thin film of the desired thickness is formed with intervals being provided between the respective thin-film forming processes. In the same way, although an example has been described where each process out of the Nc thin-film forming processes for the present invention starts as soon as a preceding process has been completed (i.e., where the Nc thin-film forming processes are carried out consecutively), it is also possible to use a method where a thin film of the desired thickness is formed with intervals being provided between the respective thin-film forming processes.

Also, with the processing condition obtaining method described above, although the processing time of X seconds required to form a thin film of the predetermined thickness Tx (in this example, the thickness zero) is found based on a direct function calculated with the thickness of the thin film formed by a thin-film forming process with the processing time set at L seconds as Ta/Na and the thickness of the thin film formed by a thin-film forming process with the processing time set at M seconds as Tb/Nb, the present invention is not limited to this. For example, it is possible to use a method that finds the “processing time of X seconds required to form a thin film of the predetermined thickness Tx” by finding the thickness Tx of the thin film formed by a thin-film forming process with the processing time set at X seconds based on the direct function described above (in this example, the direct function shown by the dashed line L3 shown in FIG. 7) and obtains the processing condition with the thickness of a thin film formed by a thin-film forming process with the processing time set at K seconds as Tc/Nc and with the thickness of the thin film formed by a thin-film forming process with the processing time set at X seconds as Tx. More specifically, as one example, it is possible to use a method where the thickness Tx (as one example, the thickness z41) of a thin film formed by the thin-film forming process with the processing time set as X seconds (as one example, zero seconds) is found based on the direct function shown by the dashed line L3 in FIG. 7, and the direct function (the control data D1 as one example of a “processing condition” for the present invention) shown by the dashed line L7 in FIG. 8 is obtained with the thickness of the thin film formed by the thin-film forming process with the processing time set at K seconds (as one example, 90 seconds) as Tc/Nc (as one example, the thickness z51 shown in FIG. 8) and the thickness of the thin film formed by the thin-film forming process with the processing time set at X seconds (as one example, zero seconds) as Tx (as one example, the thickness z41).

Also, according to this processing condition obtaining method, it is possible to obtain a processing condition based on measured values (i.e., thicknesses) of relatively thick films formed by carrying out the thin-film forming process multiple times. Accordingly, it is possible to sufficiently raise the precision of the processing condition compared to a processing condition obtained based on a measured value (i.e., thickness) of a very thin film whose thickness is difficult to measure accurately. Even if a measurement error does occur for a measured value of thickness when obtaining the processing condition, the processing condition will be obtained based on a value where the measurement error is reduced to the reciprocal of the number of processes (i.e., 1/Na, 1/Nb, and 1/Nc, all ⅓ in this example), and therefore the precision of the processing condition can be sufficiently increased. As a result, it is possible to form even an extremely thin film with the desired thickness. In addition, by finding the thickness Tx of a thin film formed by the thin-film forming process with the processing time set at X seconds (in this example, zero seconds) in advance, when subsequently obtaining the processing condition (control data D1), by merely measuring the thickness Tc of a thin film formed by carrying out the thin-film forming process with the processing time set at K seconds (in this example, 90 seconds) Nc times (in this example three times), it is possible to obtain the control data D1 corresponding to the “processing condition” for the present invention with the thickness of a thin film formed by carrying out the thin-film forming process with the processing time set at K seconds as Tc/Nc and the thickness of a thin film formed by the thin-film forming process with the processing time set at X seconds as Tx. Accordingly, compared to a processing condition obtaining method that measures the thickness Ta of a thin film formed by carrying out the thin-film forming process with the processing time set at L seconds (for example, 30 seconds) Na times (for example, three times) and measures the thickness Tb of a thin film formed by carrying out the thin-film forming process with the processing time set at M seconds (for example, 90 seconds) Nb times (for example, three times) every time the processing condition is obtained, when the processing condition is obtained for second and subsequent times, it is sufficient to form one thin film by carrying out the thin-film forming process with the processing time set at K seconds (for example, 90 seconds) Nc times (for example, three times), and therefore the processing condition (i.e., the control data D1) can be obtained in a short time.

Note that in place of a method that obtains the thickness Tx of a thin film formed by a thin-film forming process with a processing time set at zero seconds, it is possible to use a method that finds a thickness Tx of a thin film formed by a thin-film forming process with a processing time set at an arbitrary processing time (“X seconds” for the present invention: for example 10 seconds) based on the direct function described above and stores the thickness Tx in the storage unit 10. In addition, the method of finding the thickness Tx of a thin film formed by carrying out the thin-film forming process with a processing time set at 0 seconds is not limited to a method that uses the direct function shown by the dashed line L3 described above. For example, it is possible to use a method that finds the direct function shown by the dashed line L3a in FIG. 7 based on the thickness z13a of a thin film formed by carrying out a 30-second thin-film forming process three times consecutively and the thickness z23 of a thin film formed by carrying out a 90-second thin-film forming process three times consecutively and then calculates the thickness Tx (as one example, the thickness z43) of a thin film formed by the thin-film forming process with a processing time set at zero seconds based on the direct function and finds the thickness z41 corresponding to the thickness Tx for the present invention by dividing the calculation result (i.e., the thickness z43) by the number of processes (in this example, Na=Nb=3).

Also, although a thin-film forming method that forms a thin film by sputtering using the sputtering device 1 and a processing condition obtaining method for obtaining the processing condition (i.e., the control data D, D1) used in such thin-film forming method have been described, the present invention is not limited to such and it is also possible to apply the present invention to a thin-film forming process that forms a thin film by a variety of thin-film forming methods such as vacuum deposition, wet plating, and ion plating and to the obtaining of a processing condition (i.e., the control data D, D1) used during such process. During such thin-film forming processes, by using a processing condition obtained using the processing condition obtaining method according to the present invention, it is possible to set the processing time based on a processing condition that has sufficiently high precision. As a result, it is possible to form even an extremely thin film with the desired thickness.

What is claimed is:

1. A processing condition obtaining method that obtains a processing condition showing the relationship between a processing time of a thin-film forming process and the thickness of a thin film formed by the thin-film forming process, the method comprising:
measuring the thickness Ta of a thin film formed by carrying out the thin-film forming process with the processing time set at L seconds (where L is a real number) Na times (where Na is a natural number of two or greater);
measuring the thickness Tb of a thin film formed by carrying out the thin-film forming process with the processing time set at M seconds (where M is a real number that differs to L) Nb times (where Nb is a natural number of two or greater); and
obtaining the processing condition with the thickness of the thin film formed by the thin-film forming process with the processing time set at L seconds as Ta/Na and with the thickness of the thin film formed by the thin-film forming process with the processing time set at M seconds as Tb/Nb.

2. A processing condition obtaining method that obtains a processing condition showing the relationship between a processing time of a thin-film forming process and the thickness of a thin film formed by the thin-film forming process, the method comprising:
measuring the thickness Ta of a thin film formed by carrying out the thin-film forming process with the processing time set at L seconds (where L is a real number) Na times (where Na is a natural number of two or greater);
measuring the thickness Tb of a thin film formed by carrying out the thin-film forming process with the processing time set at M seconds (where M is a real number that differs to L) Nb times (where Nb is a natural number of two or greater); and
finding a processing time of X seconds required to form a thin film of a predetermined thickness Tx with the thickness of the thin film formed by the thin-film forming process with the processing time set at L seconds as Ta/Na and the thickness of the thin film formed by the thin-film forming process with the processing time set at M seconds as Tb/Nb, before measuring the thickness Tc of a thin film formed by carrying out the thin-film forming process with the processing time set at K seconds (where K is a real number) Nc times (where Nc is a natural number of two or greater) and obtaining the processing condition with the thickness of the thin film formed by the thin-film forming process with the processing time set at K seconds as Tc/Nc and with the thickness of the thin film formed by the thin-film forming process with the processing time set at X seconds as Tx.

3. A processing condition obtaining method according to claim 1, wherein the thin films are formed with Na times and Nb times set at equal numbers.

4. A processing condition obtaining method according to claim 2, wherein the thin films are formed with Na times, Nb times, and Nc times set at equal numbers.

5. A processing condition obtaining method according to claim 1, wherein when the processing condition that relates to formation of a thin film is obtained with sputtering as the thin-film forming process, the respective lengths of L seconds and M seconds are set longer than a total of the time required for a shutter mechanism of a sputtering device to open and the time required for the shutter mechanism to close.

6. A processing condition obtaining method according to claim 2, wherein when the processing condition that relates to formation of a thin film is obtained with sputtering as the thin-film forming process, the respective lengths of L seconds, M seconds, and K seconds are set longer than a total of the time required for a shutter mechanism of a sputtering device to open and the time required for the shutter mechanism to close.

7. A processing condition obtaining method according to claim 3, wherein when the processing condition that relates to formation of a thin film is obtained with sputtering as the thin-film forming process, the respective lengths of L seconds and M seconds are set longer than a total of the time required for a shutter mechanism of a sputtering device to open and the time required for the shutter mechanism to close.

8. A processing condition obtaining method according to claim 4, wherein when the processing condition that relates to formation of a thin film is obtained with sputtering as the thin-film forming process, the respective lengths of L seconds, M seconds, and K seconds are set longer than a total of the time required for a shutter mechanism of a sputtering device to open and the time required for the shutter mechanism to close.

9. A thin-film forming method that forms a thin film with the processing time set based on the processing condition obtained by the processing condition obtaining method according to claim 1.

10. A thin-film forming method that forms a thin film with the processing time set based on the processing condition obtained by the processing condition obtaining method according to claim 2.
